(19) United States
(12) Patent Application Publication
(10) Pub. No.: US 2002/0109169 A1
(43) Pub. Date: Aug. 15, 2002

(54) Capacitor of a DRAM having a wall protection structure

(76) Inventors: Yu-Ju Yang, Hsin-Chu City (TW); Yu-Hong Huang, Tainan City (TW); Ching-Ming Lee, Hsin-Chu City (TW); Kuo-Yuh Yang, Hsin-Chu (TW)

Correspondence Address: POWELL, GOLDSTEIN, FRAZER & MURPHY LLP, P.O. BOX 97233, Washington, DC, 20090-7233, US

(21) Appl. No.: 09/783,866

(22) Filed: Feb. 15, 2001

(51) Int. Cl. H01L 27/108; H01L 29/76; H01L 29/94; H01L 31/119

(52) U.S. Cl. 257/296

(57) ABSTRACT

The present invention provides a dynamic random access memory structure comprises a semiconductor substrate; semiconductor devices on the substrate, a first dielectric layer on the substrate and the semiconductor devices, and bit lines on the first dielectric layer. The bit lines are connected to bit line contact structures in the first dielectric layer. Further, a second dielectric layer is on the first dielectric layer and the bit lines. The second dielectric layer has at least a wall structure thereon and a capacitor node is in the second dielectric layer and the first dielectric layer. The capacitor node has a bottom part connected to the semiconductor substrate and a side-wall of a top part adjacent to the wall structure.

### BACKGROUND OF THE INVENTION

1. Field of the Invention

The invention relates to DRAM, and more particularly to DRAM with a capacitor structure of a DRAM.

2. Description of the Prior Art

A DRAM cell is generally constituted of a metal-oxide-semiconductor (MOS) field effect transistor and a capacitor connected to the MOS field effect transistor. With the increase of an integration density, the occupied area of each memory cell in a plan is decreased. However, the amount of storage capacitance in the limited area of a DRAM cell is very important in application. Recently, a three-dimensional structure has been proposed to provide a stacked capacitor over a bit line (COB), and to increase a height of a storage node electrode constituted of a lower plate of the stacked capacitor.

A DRAM cell with a conventional COB structure is shown in FIG. 1. A semiconductor substrate 100 is provided and thereon multitude of gate structure (word line) 120 are formed. Of course, there may be some source/drain regions and isolation device (not shown), such as field oxide, are formed in and on the semiconductor substrate 100. A tungsten silicide layer 130 is on the gate structures 120 and a first inter-polysilicon dielectric layer (IPD 1) 110 is deposited on the tungsten silicide layer 130 and the semiconductor substrate 100. A bit line structure 140 constituted of polysilicon deposited in and on the contact hole in the first inter-polysilicon dielectric layer 110 may be shown. A second inter-polysilicon dielectric layer (IPD 2) 160 is subsequently deposited on the first inter-polysilicon dielectric layer 110 and the tungsten silicide layer 150. Furthermore, a multitude of capacitor node structures 170 are constituted of polysilicon in and on the contact holds in both the first and the second inter-polysilicon layer (110 and 160).

However, those capacitor node structures 170 are so protrudent that they are susceptible to the following cleaning process and removed out. The removal of the capacitor node structures may result in damages in some characteristics.

### SUMMARY OF THE INVENTION

It is an object of the present invention to provide a capacitor structures of a DRAM cell. The capacitor node structures in a DRAM cell are formed between multitude of wall structures constituted of inter-polysilicon layer.

It is another object of the present invention to provide a structure of reducing the removal of the capacitor during DRAM manufacture process. The capacitor node structures can be protected from water or mega-sonic flow during cleaning steps.

In the present invention, a dynamic random access memory structure comprises a semiconductor substrate; semiconductor devices on the substrate, a first dielectric layer on the substrate and the semiconductor devices, and bit lines on the first dielectric layer. The bit lines are connected to bit line contact structures in the first dielectric layer. Further, a second dielectric layer is on the first dielectric layer and the bit lines. The second dielectric layer has at least a wall structure thereon and a capacitor node is in the second dielectric layer and the first dielectric layer. The capacitor node has a bottom part connected to the semiconductor substrate and a side-wall of a top part adjacent to the wall structure.

### BRIEF DESCRIPTION OF THE DRAWINGS

A better understanding of the invention may be derived by reading the following detailed description with reference to the accompanying drawing wherein:

FIG. 1 is a cross-sectional schematic diagram illustrating a DRAM cell of a COB structure in accordance with the prior art; and

FIGS. 2A-2E are a series of cross-sectional schematic diagrams illustrating a DRAM cell of a COB structure manufactured in accordance with the present invention.

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a dynamic random access memory structure comprises a semiconductor substrate; semiconductor devices on the substrate, a first dielectric layer on the substrate and the semiconductor devices, and bit lines on the first dielectric layer. The bit lines are connected to bit line contact structures in the first dielectric layer. Further, a second dielectric layer is on the first dielectric layer and the bit lines. The second dielectric layer has at least a wall structure thereon and a capacitor node is in the second dielectric layer and the first dielectric layer. The capacitor node has a bottom part connected to the semiconductor substrate and a side-wall of a top part adjacent to the wall structure.

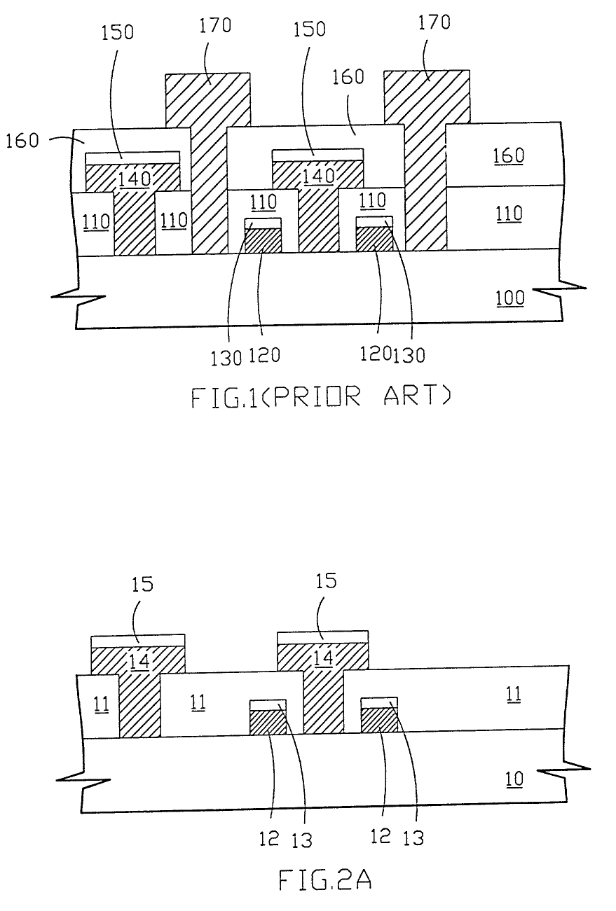

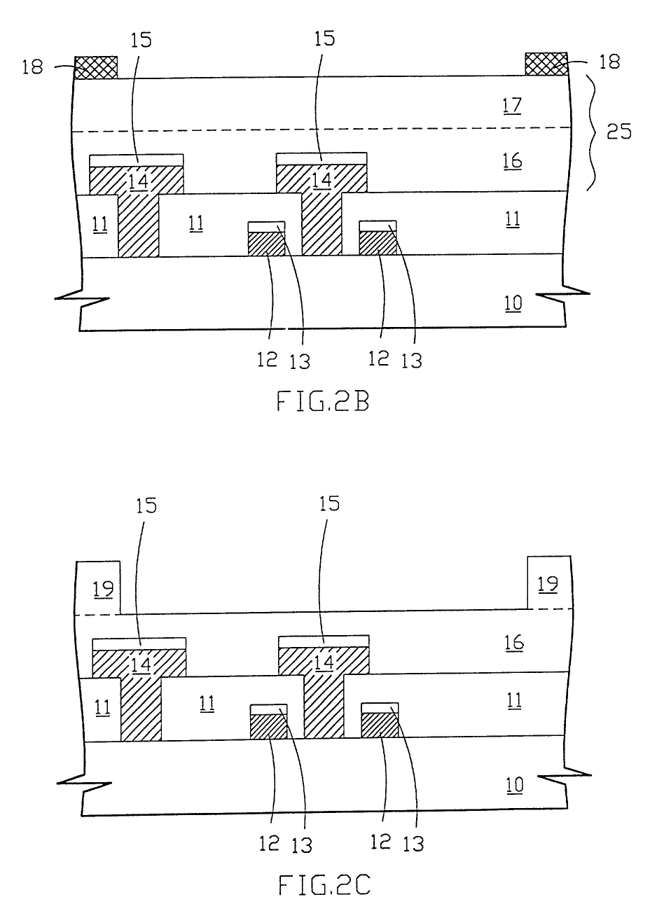

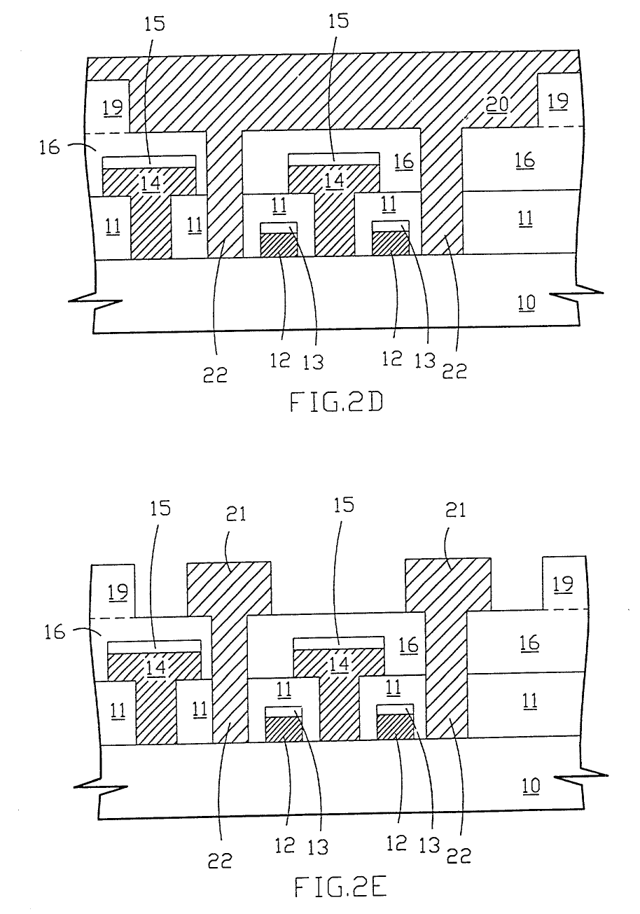

One embodiment of the present invention is depicted in FIGS. 2A-2E. Shown in FIG. 2A, a semiconductor substrate 10 is provided and thereon a multitude of devices 12, such as gate structures (word line), are formed. Of course, there may be some source/drain regions and isolation device (not shown), such as field oxide, are formed in and on the semiconductor substrate 10. A tungsten silicide layer 13 is on the gate structures 12 and then a first dielectric layer 11, such as inter-polysilicon dielectric (IPD) or polycide, is deposited on the tungsten silicide layer 13 and the semiconductor substrate 10. Next, a multitude of conductive lines 14, such as bit lines, constituted of polysilicon deposited in and on the contact holes in the first dielectric layer 11 may be shown. Further, a tungsten silicide layer 15 is also formed on the conductive lines 14.

Referring to FIG. 2B, a second dielectric layer 25, such as inter-polysilicon dielectric layer, is subsequently deposited over the first dielectric layer 11 and the tungsten silicide layer 15. To be specific, in FIG. 2B, the second dielectric layer 25 is constituted of a first portion 16 and a second portion 17 for the following illustrations. In fact, the first portion 16 and the second portion 17 are the second dielectric layer 25. Next, a mask of wall structures 18 is on the second portion 17 for forming a multitude of wall structures.

Next, as a key step of the present invention depicted in FIG. 2C, the second portion 17 of the second dielectric layer 25 are etched by using the mask of wall structures 18 as an etch mask. A multitude of wall structures 19 are remained after etch of the second portion 17. The wall structures 19 are also constituted of the second dielectric layer 25 and protruded on the first portion 16 of the second dielectric layer 25.

Next, a pattern of capacitor contacts (not shown) is first transferred on the first portion 16. Then the first portion 16 of the second dielectric layer 25 and the first dielectric layer 11 are etched to form some capacitor contact openings. Next, a polysilicon layer 20, such as silicon nitride, is deposited into the capacitor contact openings, the wall structures 19, and the first portion 16 of the second dielectric layer 25 to form the capacitor contacts 22.

Next, referring to FIG. 2E, the polysilicon layer 20 is first planarized by the method of chemical mechanical polishing. A pattern of capacitor node structures (not shown) is transferred on the polysilicon layer 20 and thereafter the polysilicon layer 20 is etched to form multitude of capacitor node structures 21 connected to the capacitor contacts 22. To be specific, the wall structures 19 are parallel to and around the capacitor node structures 21. The wall structures 19 can protect the capacitor node structures 21 from water or mega-sonic flow during the subsequent clean step and further reduce the risk of removal of the capacitor node structures 21.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A capacitor structure of a dynamic random access memory cell, said capacitor structure comprising:
a semiconductor substrate;
a plurality of semiconductor devices on said semiconductor substrate;
a first dielectric layer on said semiconductor substrate and said semiconductor devices;
a plurality of bit lines on said first dielectric layer, said bit lines connected to a plurality of bit line contact structures in said first dielectric layer;
a second dielectric layer on said first dielectric layer and said bit lines, said second dielectric layer having at least a wall structure thereon; and
a capacitor node in said second dielectric layer and said first dielectric layer, said capacitor node having a bottom part connected to said semiconductor substrate and a side-wall of a top part adjacent to said wall structure.

2. The capacitor structure of claim 1, wherein said semiconductor devices comprise a gate structure.

3. The capacitor structure of claim 1, wherein said bit lines are formed by polysilicon deposition.

4. The capacitor structure of claim 1, wherein said first dielectric layer comprises an inter-polysilicon dielectric layer.

5. The capacitor structure of claim 1, wherein said second dielectric layer comprises an inter-polysilicon dielectric layer.

6. A capacitor structure in a dynamic random access memory cell, said capacitor structure comprising:
a semiconductor substrate;
a plurality of gate structures on said semiconductor substrate;
a first inter-polysilicon dielectric layer on said semiconductor substrate and said gate structures;
a plurality of bit lines on said first inter-polysilicon dielectric layer, said bit lines connected to a plurality of bit line contact structures in said first inter-polysilicon dielectric layer;
a second inter-polysilicon dielectric layer on said first inter-polysilicon dielectric layer and said bit lines, said second inter-polysilicon dielectric layer having at least a wall structure thereon; and
a capacitor node on said second inter-polysilicon dielectric layer and said first inter-polysilicon dielectric layer, said capacitor node having a bottom part connected to said semiconductor substrate and a side-wall of a top part adjacent to said wall structure.

7. The capacitor structure of claim 6, wherein said bit lines and said bit line contacts are made of polysilicon.

8. The capacitor structure of claim 6, wherein said bit lines and said bit line contacts are made of polycilide.

9. The capacitor structure of claim 6, wherein said capacitor node is made of polycilide.
